(19) United States
(12) Patent Application Publication
(10) Pub. No.: US 2008/0315311 A1
(43) Pub. Date: Dec. 25, 2008

(54) Semiconductor device

(75) Inventor: Satoru Okamoto, Isehara (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 12/213,272

(22) Filed: Jun. 17, 2008

(30) Foreign Application Priority Data
Jun. 22, 2007 (JP) 2007-164552

(51) Int. Cl. H04B 7/00; H01L 29/786; G08B 13/14; H01Q 17/00

(52) U.S. Cl. 257/347; 340/572.7; 29/601; 257/E29.273

(57) ABSTRACT

An object is to provide a semiconductor device in which an antenna is not bent and electric waves can be transmitted and received even if a substrate is bent and in which a thin and flexible substrate can be used. The present invention relates to a semiconductor device characterized in that it has an antenna having a spiral shape, a zigzag shape, a comb shape, a lattice shape, a radial shape or a net shape, which is formed using a superelastic alloy material or a shape-memory alloy material over at least one entire surface of a flat and flexible substrate; and a circuit including a thin film transistor, which is connected to the antenna.

### BACKGROUND OF THE INVENTION

1. Field of the Invention

The present invention relates to a semiconductor device capable of wireless communication in which an antenna is formed using a superelastic alloy material or a shape-memory alloy material and a manufacturing method thereof.

2. Description of the Related Art

In recent years, ID chips such as RFID (radio frequency identification system) have been researched and put into practical use as an information and communication technology utilizing electromagnetic waves (see Patent Document 1: Japanese Published Patent Application No. 2006-139330).

RFID refers to a communication technology over electromagnetic waves between a reader/writer and a semiconductor device capable of wirelessly transmitting and receiving information (also called an RFID tag, an RF tag, an ID tag, an IC tag, a wireless tag, an electronic tag, or a wireless chip), so that data can be stored in or read out from the semiconductor device. Such a semiconductor device includes an antenna and an integrated circuit having a signal processing circuit provided with a memory circuit and the like.

A semiconductor device used for RFID, by which information can be transmitted and received wirelessly, obtains an operating power by electromagnetic induction from electric waves that are received from a reader/writer, and exchanges data with the reader/writer by utilizing the electric waves. In general, a semiconductor device by which information can be transmitted and received wirelessly has an antenna which transmits and receives such electric waves and which is formed separately from an integrated circuit and connected to the integrated circuit.

Since an antenna is formed over a base, when the base is bent, the antenna might also be bent. When the antenna is bent, a problem in that electric waves from the reader/writer cannot be received or electric waves to the reader/writer cannot be transmitted arises.

Further, an antenna formed using a conventional conductive material needs to be formed over a supporting substrate that is hard and strong in order to prevent cutting or change in shape. In many cases, such a supporting substrate is formed using a material with large thickness.

### SUMMARY OF THE INVENTION

It is an object of the present invention to provide a semiconductor device in which an antenna is not bent and electric waves can be transmitted and received even if a substrate is bent and in which a thin and flexible substrate can be used.

In the present invention, as a material of an antenna, a superelastic alloy material that is a conductor, which is bent by external force and returns to its original shape by removing the external force; or a shape-memory alloy material that is a conductor, which returns to its original shape by heating is used.

The present invention relates to a semiconductor device characterized in that it has an antenna having a spiral shape, a zigzag shape, a comb shape, a lattice shape, a radial shape or a net shape, which is formed using a superelastic alloy material or a shape-memory alloy material over at least one entire surface of a flat and flexible substrate; and a circuit including a thin film transistor, which is connected to the antenna.

In the present invention, the superelastic alloy material or the shape-memory alloy material is an alloy containing a transition metal.

In the present invention, the transition metal is any one of vanadium, chromium, manganese, iron, or cobalt.

In the present invention, the superelastic alloy material or the shape-memory alloy material is any one of an alloy containing cadmium, an alloy containing titanium and nickel, an alloy containing nickel, an alloy containing copper, an alloy containing indium, or an alloy containing iron.

In the present invention, the alloy containing cadmium is Au—Cd or Ag—Cd; the alloy containing titanium and nickel is any one of Ti—Ni, Ti—Ni—Cu, Ti—Ni—Fe, or Ti—Pd—Ni; the alloy containing nickel is Ni—Al; the alloy containing copper is any one of Cu—Al—Ni, Cu—Au—Zn, Cu—Sn, or Cu—Zn; the alloy containing indium is In—Ti or In—Cd; the alloy containing iron is any one of Fe—Pt, Fe—Pd, Fe—Mn—Si, or Fe—Ni—Co—Ti.

In the present invention, the superelastic alloy material or the shape-memory alloy material is an alloy containing any one of copper, aluminum, silver, gold, nickel, or titanium.

In the present invention, the substrate is formed using any one of a film, paper, or thinned plastic.

In the present invention, the superelastic alloy material or the shape-memory alloy material is used as a material of the antenna, whereby the antenna can return to its original shape even if it is bent.

Further, the antenna that returns to its original shape is formed over an entire surface of a supporting substrate, whereby planarity of a semiconductor device as a whole including a base can be kept.

According to the present invention, a thin supporting substrate can be used; thus, the thickness of the semiconductor device as a whole can be 0.76 mm or less, preferably 0.25 mm or less, more preferably 0.1 mm or less which is small.

According to the present invention, even if a supporting substrate is bent, an antenna is not bent and is not cut, so that a highly reliable semiconductor device capable of wireless communication can be obtained.

### BRIEF DESCRIPTION OF THE DRAWINGS

In the accompanying drawings:

FIGS. 1A to 1E are cross sectional views showing a manufacturing process of a semiconductor device of the present invention;

FIGS. 2A to 2E are cross sectional views showing a manufacturing process of a semiconductor device of the present invention;

FIGS. 3A to 3C are cross-sectional views showing a manufacturing process of a semiconductor device of the present invention;

FIGS. 4A and 4B are cross-sectional views showing a manufacturing process of a semiconductor device of the present invention;

FIGS. 5A to 5D are perspective views showing an arrangement of an antenna of the present invention;

FIGS. 6A and 6B are views showing an example in which a semiconductor device of the present invention is used;

FIG. 7 is a block diagram of a semiconductor device of the present invention;

FIGS. 8A to 8H are views each showing an example in which a semiconductor device of the present invention is used;

FIGS. 9A and 9B are views showing an example in which a semiconductor device of the present invention is used;

FIGS. 10A and 10B are views showing an example in which a semiconductor device of the present invention is used;

FIGS. 11A to 11C are perspective views each showing an arrangement of an antenna of the present invention; and

FIGS. 12A and 12B are perspective views each showing an arrangement of an antenna of the present invention.

### DETAILED DESCRIPTION OF THE INVENTION

Embodiment modes of the present invention will be hereinafter described with reference to the drawings. However, the present invention is not limited to the description given below, and it will be readily apparent to those skilled in the art that various changes and modifications in modes and details thereof can be made without departing from the purpose and scope of the present invention. Therefore, unless such changes and modifications depart from the purport and the scope of the present invention, they should be construed as being included therein. Note that in the structure of the present invention which is hereinafter described, the reference numerals denoting the same portions are used in common in different drawings.

### Embodiment Mode 1

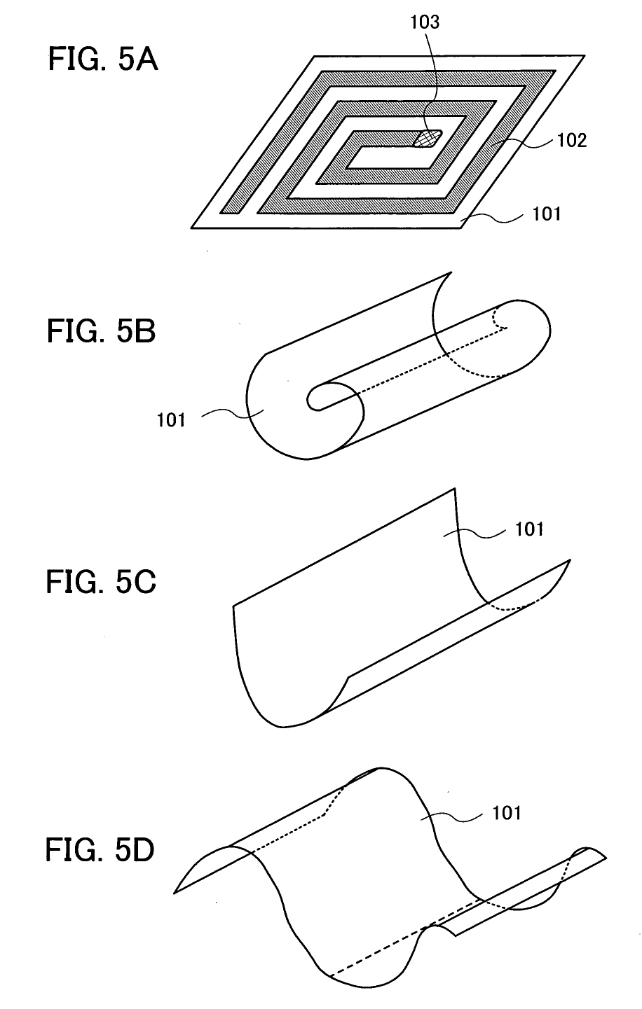

Arrangement of an antenna in this embodiment mode is shown in FIGS. 5A to 5D. A semiconductor device shown in FIG. 5A includes a semiconductor device 103 capable of wireless communication and an antenna 102 over a supporting substrate 101. The antenna 102 is arranged evenly in a planar manner over the supporting substrate 101 and the antenna 102 keeps a shape of the supporting substrate 101 as well as its own shape.

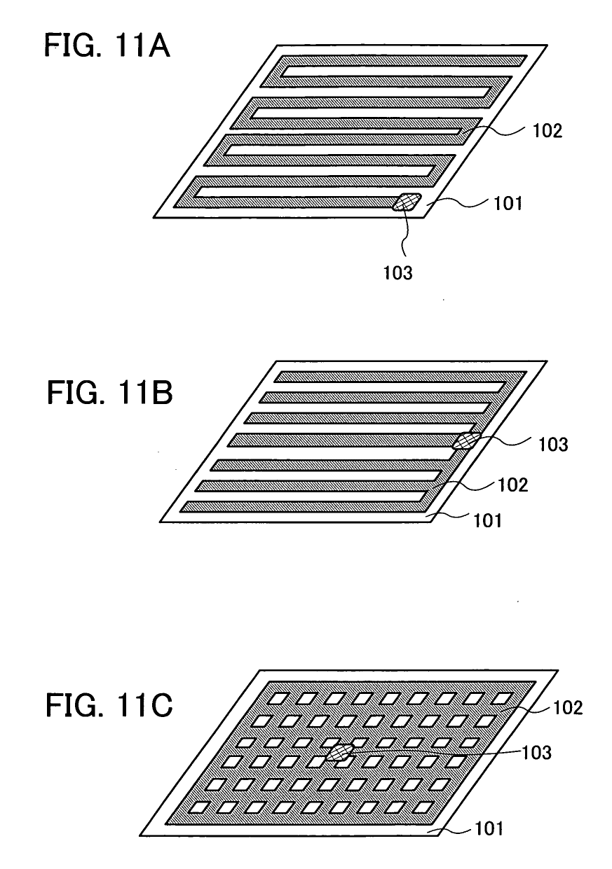

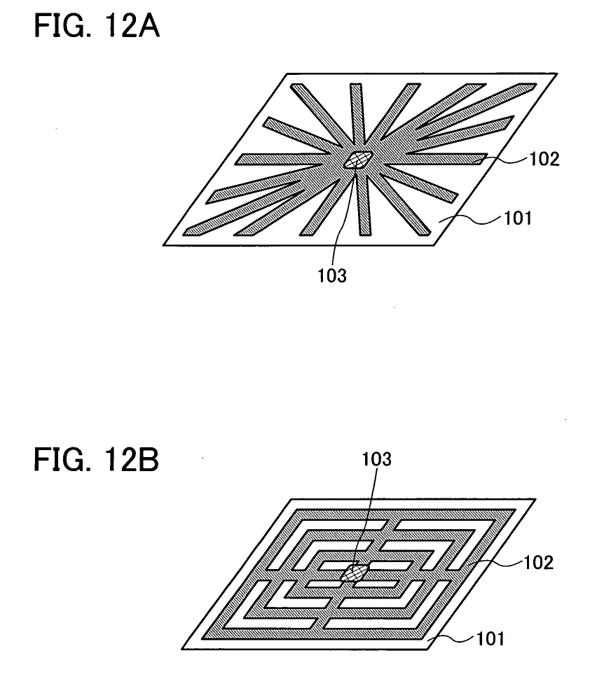

The antenna 102 is arranged evenly with a constant width over an entire surface of the supporting substrate 101. For example, the antenna 102 may have a spiral shape as shown in FIG. 5A. Alternatively, the antenna 102 may also have a zigzag shape (see FIG. 11A), a comb shape (see FIG. 11B), a lattice shape (see FIG. 11C), a radial shape (see FIG. 12A), a net shape (see FIG. 12B) or the like. The shape of the antenna 102 may be determined as necessary.

The antenna 102 is formed using an alloy with a superelastic property or a shape-memory alloy. An alloy containing cadmium (Cd) such as Au—Cd, Ag—Cd or the like, an alloy containing titanium (Ti) and nickel (Ni) such as Ti—Ni, Ti—Ni—Cu, Ti—Ni—Fe, Ti—Pd—Ni or the like, an alloy containing nickel (Ni) such as Ni—Al or the like, an alloy containing copper (Cu) such as Cu—Al—Ni, Cu—Au—Zn, Cu—Sn, Cu—Zn or the like, an alloy containing indium (In) such as In—Ti, In—Cd, or the like, and an alloy containing iron (Fe) such as Fe—Pt, Fe—Pd, Fe—Mn—Si, Fe—Ni—Co—Ti, or the like can be given. In addition, an alloy containing a transition metal such as vanadium (V), chromium (Cr), manganese (Mn), iron (Fe), cobalt (Co), or the like can also be used.

An alloy containing copper (Cu), aluminum (Al), silver (Ag), gold (Au), nickel (Ni), titanium (Ti), or the like is preferable as a material used for the antenna 102 because it has a low resistance value.

An alloy with a superelastic property or a shape-memory alloy can be formed by a melting method such as a high frequency melting method, an arc melting method or the like, a sputtering method, or a printing method such as an ink-jet method.

When a melting method is used, a mold which is cut out in accordance with the shape of the antenna 102 is prepared and an alloy having the shape of the antenna 102 can be formed by pouring a molten alloy into the mold.

There is a limitation on a thickness of the antenna 102. When the antenna 102 is formed using a thin film with a thickness of less than or equal to 100 μm, preferably 0.1 to 30 μm, more preferably 1 to 20 μm, the antenna 102 is preferably formed by a sputtering method or a printing method such as an ink-jet method.

When an alloy to be the antenna 102 is formed by a sputtering method, a target including a desired alloy may be used. Alternatively, a plurality of targets containing each element included in desired alloys as its main component may be used. Further alternatively, an alloy may be formed by arranging one or plural kinds of pellets of an element contained in an alloy over a target containing one or plural kinds of elements contained in the alloy.

Sputtering using a plurality of targets or sputtering using a pellet is preferable in that the composition ratio of the element in the alloy can be adjusted. On the other hand, using the target including a desired alloy leads to improvement in throughput since adjustment of the composition ratio thereof is completed, which is preferable in consideration of mass production. However, the present invention is not limited to the above-described method as long as a desired alloy can be formed.

For formation of the antenna 102, a mask may be arranged between a target and an object to be formed. Alternatively, the antenna 102 may be formed by etching after formation of an alloy. For etching, wet etching or dry etching is performed using a mask such as a resist or the like.

When a printing method such as an ink-jet method or the like is used, printing may be performed after a metal paste or an alloy paste is prepared by dispersing fine particles of an element contained in a desired alloy into a solvent or a paste and is mixed at a desired ratio. Alternatively, the metal paste or the alloy paste may be mixed while printing. The paste becomes an alloy by heat treatment after printing. An alloy is formed and crystallized at the same time by optimizing a temperature of heat treatment to form an alloy having crystallinity, which is preferable. A mold or a mask for determining the shape of the antenna 102 is not necessary when a printing method is used, which leads to reduction in cost and improvement in throughput. When there is a concern that the fine particles of the metal element or the fine particles of the alloy are oxidized in printing, printing may be performed under an inert gas atmosphere or under a reduced pressure atmosphere. Alternatively, the heat treatment may be performed under a reducing atmosphere.

Each of the alloy with a superelastic property and the shape-memory alloy which are formed by the above method has two types of alloys: an alloy which has crystallinity and an alloy which does not have crystallinity. Crystallization is preferably performed by heat treatment in order that an alloy may have crystallinity.

As an apparatus for crystallization, a furnace such as an electrically heated furnace or a furnace having a function of RTA can be used. Heat treatment is performed at temperatures of 600 to 1200K, preferably 700 to 800K for 10 minutes to 10 hours in accordance with an alloy material.

When the obtained alloy includes a martensite layer, the alloy is heated to a temperature greater than or equal to the temperature at which the layer is transferred and austenite transformation occurs to form an austenite layer. A temperature at which the austenite layer is formed is referred to as an austenite transformation (reverse transformation) start temperature. The austenite transformation start temperature depends on an alloy to be formed. The alloy has a superelastic property by this treatment. An apparatus for austenite transformation is not particularly limited as long as it can bring an alloy to greater than or equal to a phase transition temperature which is specific to the alloy.

Crystallization or heat treatment is performed to the alloy having the shape of the antenna 102 as necessary to form an austenite layer, whereby the antenna 102 formed using an alloy with a superelastic property is formed.

When the obtained alloy includes an austenite layer, martensitic transformation occurs by cooling the alloy to less than or equal to the layer transition temperature to form a martensitic layer. A temperature at which the martensitic layer is formed is referred to as martensitic transformation start temperature. The martensitic transformation start temperature depends on an alloy to be formed. The alloy has a shape-memory property by this treatment. An apparatus for martensitic transformation is not particularly limited as long as it can bring an alloy to less than or equal to a phase transition temperature which is specific to the alloy.

Crystallization or cooling treatment is performed to the alloy having the shape of the antenna 102 as necessary to form a martensitic layer, whereby the antenna 102 made of an alloy with a shape-memory property is formed.

As a material of the supporting substrate 101, any base material may be used as long as it is flat (sheet-like) and flexible. For example, a film, paper, or thinned plastic which cannot be used conventionally due to the strength may also be used.

A substrate using the same material as the supporting substrate 101 may be provided over the supporting substrate 101 which is provided with the semiconductor device 103 capable of wireless communication and the antenna 102. That is, a structure may be employed in which the semiconductor device 103 capable of wireless communication and the antenna 102 are interposed between the two of the supporting substrate 101 and the substrate using the same material as the supporting substrate 101.

The strength of the semiconductor device formed in this embodiment mode is secured by the antenna 102 formed using an alloy with a superelastic property or a shape-memory alloy; thus, the strength is not required for the supporting substrate 101.

Even if the supporting substrate 101 curls up (see FIG. 5B) or is bent (see FIGS. 5C and 5D), as long as the antenna 102 is formed using an alloy with a superelastic property, the shape of the antenna 102 over the supporting substrate 101 returns to its original shape without heat treatment. The shape of the antenna 102 over the supporting substrate 101 returns to its original shape by heat treatment, as long as the antenna 102 is formed using a shape-memory alloy.

When the antenna 102 is arranged over an entire surface of the supporting substrate 101 as shown in FIG. 5A, the semiconductor device as a whole is prevented from being bent, so that a highly reliable semiconductor device can be obtained.

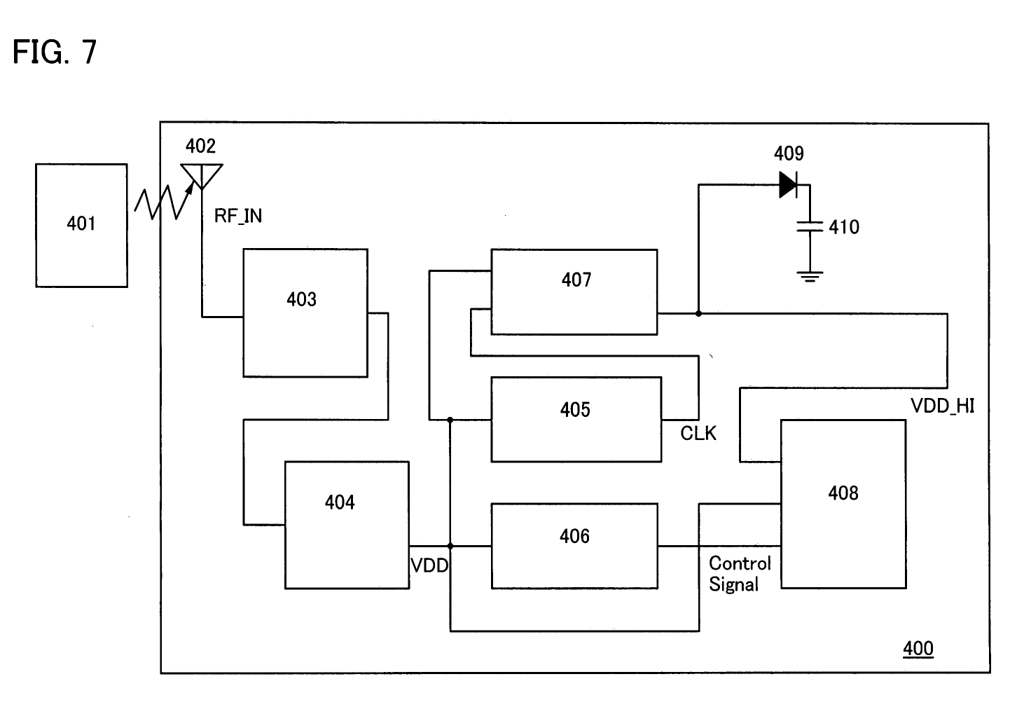

FIG. 7 is a diagram which shows an example of a block diagram of a circuit layout of the semiconductor device capable of wireless communication in this embodiment mode.

In FIG. 7, a reader/writer 401 is a device for writing and reading data in and from a semiconductor device 400 capable of wireless communication from outside without contact. The semiconductor device 400 capable of wireless communication includes an antenna portion 402 for receiving electric waves; a rectifier circuit 403 for rectifying the output of the antenna portion 402; a regulator circuit 404 for outputting operating voltage VDD to each circuit upon the receipt of the output from the rectifier circuit 403; a clock generator circuit 405 for generating clock upon the receipt of the output from the regulator circuit 404; a booster circuit 407 for supplying data-writing voltage to a memory circuit 408 that carries out data writing or reading, upon the receipt of the output from a logic circuit 406; a backflow prevention diode 409 to which the output of the booster circuit 407 is to be inputted; a battery capacitor 410 in which the output of the backflow prevention diode 409 is to be inputted to accumulate charges; and the logic circuit 406 for controlling a circuit such as the memory circuit 408.

Although not particularly shown here, there may additionally be a data modulator/demodulator circuit, a sensor, an interface circuit, and the like. With such a structure, the semiconductor device 400 capable of wireless communication can communicate information with the reader/writer 401 without contact.

In the above structure of the semiconductor device 400 capable of wireless communication, the portion other than the antenna portion 402 can be the integrated circuit, and the antenna and the integrated circuit can be formed over one substrate.

Although this embodiment mode explains the example of the semiconductor device capable of wireless communication provided with the battery capacitor 410 as a wirelessly chargeable battery (radio frequency battery, or noncontact battery by radio frequency), the battery capacitor 410 is not necessarily provided. In that case, the backflow prevention diode 409 is also unnecessary.

Moreover, the capacitor is used as a charging element for accumulating charges (also called battery); however, the present invention is not limited to this. In this embodiment mode, the battery refers to a wirelessly chargeable battery of which continuous operation time can recover by being charged. Further, as the battery, a thin sheet-like battery or a roll-like battery with a small diameter is preferably used, although the type of battery used may differ depending on the intended use. For example, size reduction is possible with a lithium battery, preferably a lithium polymer battery using gel electrolyte, a lithium ion battery, or the like. Needless to say, the battery may be any kind of chargeable battery, such as a nickel metal hydride battery, a nickel cadmium battery, an organic radical battery, a lead-acid battery, an air secondary battery, a nickel-zinc battery, a silver-zinc battery, or a capacitor with high capacity.

Note that as a capacitor with high capacity that can be used as a battery of this embodiment mode, it is preferable to use a capacitor having electrodes whose opposed areas are large. In particular, it is preferable to use a double-layer electrolytic capacitor which is formed using an electrode material having a large specific surface area, such as activated carbon, fullerene, or a carbon nanotube. A capacitor has a simpler structure than a battery, and further, a capacitor can be easily formed to be thin and formed by stacking layers. A double-layer electrolytic capacitor has a function of storing power and will not deteriorate that much even after it is charged and discharged a number of times. Further, a double-layer electrolytic capacitor has an excellent property that it can be charged rapidly.

In the present invention, the antenna is disposed in the center of the semiconductor device capable of wireless communication, which improves the capability of the power source produced in the semiconductor device capable of wireless communication and therefore enhances the charging efficiency.

In this embodiment mode, the antenna portion, the rectifier circuit portion, and the booster circuit used in the semiconductor device capable of wireless communication are also used as the antenna portion, the rectifier circuit portion, and the booster circuit portion in the wirelessly chargeable battery; therefore, the reader/writer 401 can be used as a signal generating source for charging the battery capacitor 410 at the same time as operating the semiconductor device capable of wireless communication.

The wirelessly chargeable battery shown in this embodiment mode can charge an object without contact, and is very easy to be carried. When the battery is provided in the semiconductor device capable of wireless communication, a memory which needs a power source, such as SRAM, can be mounted, which can contribute to sophistication of the semiconductor device capable of wireless communication.

However, the present invention is not limited to this structure, and a part or all of the antenna portion, the rectifier circuit portion, and the booster circuit may be separated for RFID operation and for charge of the wirelessly chargeable battery. For example, when the antenna portion 402 is separated for the antenna portion for RFID operation and the antenna portion for charge of the wirelessly chargeable battery, the frequency of signals used for RFID operation and the frequency of signals for charge of the wirelessly chargeable battery can be different from each other. In this case, the signals generated from the reader/writer 401 and the signals generated from the signal generating source to the wirelessly chargeable battery are preferably in the frequency range where the both signals do not interfere with each other.

When the antenna portion, the rectifier circuit portion, and the booster circuit are used in common for RFID operation and for charge of the wirelessly chargeable battery, the following structure may be employed: a switching element is disposed between the wirelessly chargeable battery and the booster circuit, and the booster circuit and the wirelessly chargeable battery are disconnected from each other by turning off the switch during writing operation, whereas they are connected to each other by turning on the switch during the time other than the writing operation. In this case, since the battery is not charged during the writing operation, voltage drop during the writing operation can be avoided. The switching element can have a known structure.

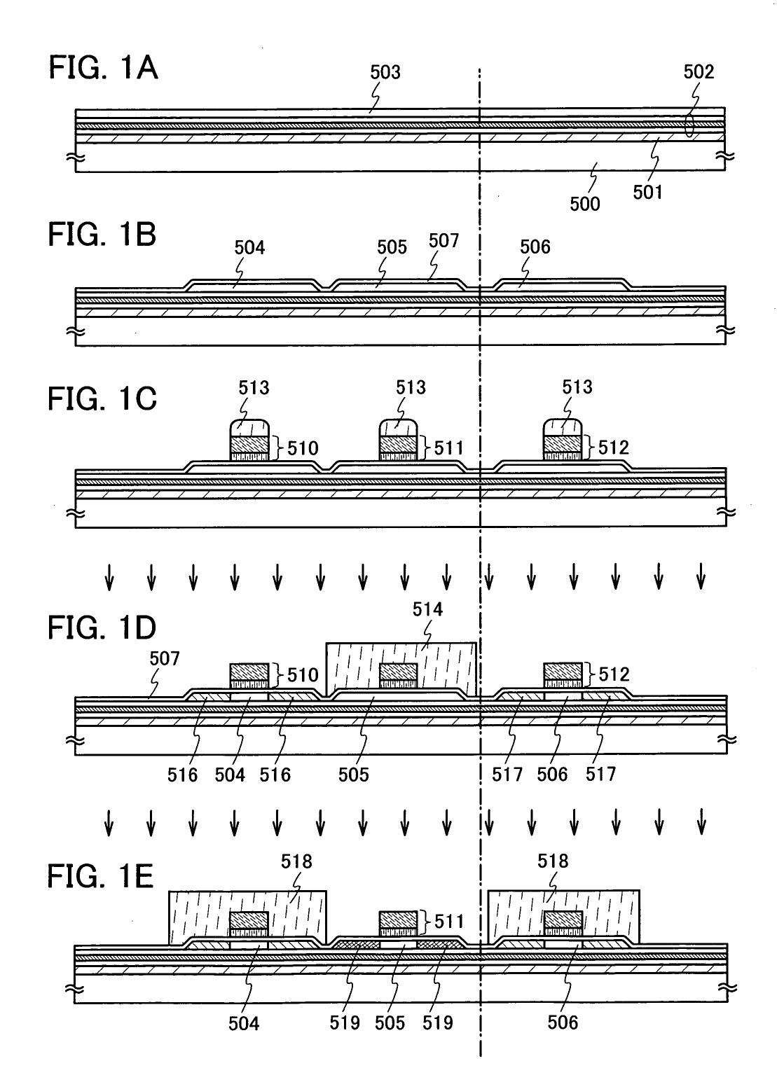

Next, a manufacturing process of the semiconductor device capable of wireless communication in this embodiment mode will be described with reference to FIGS. 1A to 1E, FIGS. 2A to 2E, FIGS. 3A to 3C, FIGS. 4A and 4B.

First, a separation layer 501 is formed over a first substrate 500 having heat resistance as shown in FIG. 1A. The first substrate 500 may be, for example, a glass substrate such as a barium borosilicate glass substrate or an aluminoborosilicate glass substrate, a quartz substrate, a ceramic substrate, or the like. Moreover, the first substrate 500 may be a semiconductor substrate or a metal substrate including a stainless steel substrate. A substrate formed of a synthetic resin having flexibility, such as plastic, generally tends to have lower allowable temperature limit than the above-described substrates; however, the substrate can be used as long as it can withstand a processing temperature in manufacturing steps.

The separation layer 501 can be formed by a sputtering method, a reduced-pressure CVD method, a plasma CVD method, or the like by using a layer containing silicon such as amorphous silicon, polycrystalline silicon, single-crystal silicon, or microcrystalline silicon (including semi-amorphous silicon) as its main component. In this embodiment mode, the separation layer 501 is formed of amorphous silicon with a thickness of about 50 nm by a reduced-pressure CVD method. The material of the separation layer 501 is not limited to silicon and may be of any kind as long as it can be selectively etched away. The thickness of the separation layer 501 is preferable in the range of from 10 to 100 nm. When semi-amorphous silicon is used, the thickness may be in the range of from 30 to 50 nm.

Next, a base film 502 is formed over the separation layer 501. The base film 502 is provided in order to prevent alkaline-earth metal or alkali metal such as Na in the first substrate 500 from diffusing into the semiconductor film, thereby preventing an adverse effect on characteristics of the semiconductor element such as a TFT (Thin Film Transistor). The base film 502 also works to protect the semiconductor element during a later step of separating the semiconductor elements. The base film 502 may be either a single insulating film or stacked insulating films. Therefore, an insulating film which can prevent alkali metal and alkaline-earth metal from diffusing into the semiconductor film, such as a silicon oxide film, a silicon nitride film, or a silicon nitride oxide film is used.

In this embodiment mode, the base film 502 is formed in such a manner that a 100-nm-thick silicon oxide film containing nitrogen, a 50-nm-thick silicon nitride film containing oxygen, and a 100-nm-thick silicon oxide film containing nitrogen are stacked in order; however, the material, thickness, and number of stacked films are not limited to these. For example, the silicon oxide film containing nitrogen as the lower layer may be replaced by a siloxane-based resin film with a thickness of 0.5 to 3 μm which is formed by a spin coating method, a slit coating method, a droplet discharging method, a printing method, or the like. The silicon nitride film containing oxygen as the middle layer may be replaced by a silicon nitride film. The silicon oxide film containing nitrogen as the upper layer may be replaced by a silicon oxide film. The thickness of each film is preferably in the range of from 0.05 to 3 μm, and can be freely selected from that range.

Here, the silicon oxide film can be formed by thermal CVD, plasma CVD, normal pressure CVD, bias ECRCVD, or the like with the use of a mixed gas of silane and oxygen, a mixed gas of TEOS (tetraethyl orthosilicate) and oxygen, or the like. The silicon nitride film can be formed typically by plasma CVD with the use of a mixed gas of SiH₄ and NH₃. The silicon oxide film containing nitrogen and the silicon nitride film containing oxygen can be formed typically by plasma CVD with the use of a mixed gas of silane and nitrous oxide.

Next, a semiconductor film 503 is formed over the base film 502. It is preferable that the semiconductor film 503 be formed without being exposed to the air after the formation of the base film 502. The semiconductor film 503 has a thickness of 20 to 200 nm (preferably 40 to 170 nm, more preferably 50 to 150 nm). The semiconductor film 503 may be formed of an amorphous semiconductor, a semi-amorphous semiconductor, or a polycrystalline semiconductor. Instead of silicon, silicon germanium may be used as the semiconductor. In the case of using silicon germanium, the concentration of germanium is preferably in the range of from about 0.01 to 4.5 atomic %.

The semiconductor film 503 may be crystallized by a known technique. Known crystallization methods include a laser crystallization method using laser light and a crystallization method using a catalytic element. Alternatively, a laser crystallization method using laser light and a crystallization method using a catalytic element may be used in combination. When the first substrate 500 is a heat-resistant substrate such as a quartz substrate, high-temperature annealing at about 950° C. may be combined with any of a thermal crystallization method using an electrically heated oven, a lamp annealing crystallization method using infrared light, or a crystallization method using a catalytic element.

For example, in the case of carrying out laser crystallization, the semiconductor film 503 is subjected to thermal annealing at 500° C. for an hour before laser crystallization. This thermal annealing can increase the resistance of the semiconductor film 503 against laser. Then, a continuous wave solid-state laser is used to irradiate the semiconductor film 503 with laser light of any of second to fourth harmonic waves of a fundamental wave; thus, crystals with large grain diameter can be obtained. For example, typically, a second harmonic (532 nm) or a third harmonic (355 nm) of a Nd:YVO₄ laser (fundamental wave: 1064 nm) is preferably used. Specifically, laser light emitted from a continuous wave YVO₄ laser is converted into a harmonic wave through a non-linear optical element, and thus laser light with a power of 10 W is obtained. Then, the laser light is preferably shaped into rectangular or elliptical laser light on an irradiated surface through an optical system, and is delivered onto the semiconductor film 503. The power density of the laser light at this time is necessary to range from about 0.01 to 100 MW/cm² (preferably 0.1 to 10 MW/cm²). The irradiation is then performed by setting the scan speed in the range of from about 10 to 2000 cm/sec.

Alternatively, the laser crystallization may be performed by using a pulsed laser with a repetition rate of 10 MHz or more, which is extremely higher than generally used lasers having a repetition rate of several tens to several hundreds of hertzs. It is said that it takes several tens to several hundreds of nanoseconds to completely solidify a semiconductor film after the semiconductor film is irradiated with pulsed laser light. When the pulsed laser light has the above-described repetition rate, the semiconductor film can be irradiated with laser light before the semiconductor film melted by previous laser light is solidified. Therefore, a solid-liquid interface can be continuously moved in the semiconductor film so that crystal grains which have continuously grown in a scanning direction are formed in the semiconductor film. Specifically, it is possible to form an aggregation of crystal grains each having a width of approximately 10 to 30 μm in the scanning direction and a width of approximately 1 to 5 μm in a direction perpendicular to the scanning direction. It is also possible to form a semiconductor film having almost no crystal grain boundaries at least in a channel direction of the TFT by forming a crystal grain of a single crystal that is extended long along the scanning direction.

The laser crystallization may be performed by simultaneously delivering continuous wave laser light of a fundamental wave and continuous wave laser light of a harmonic wave, or simultaneously delivering continuous wave laser light of a fundamental wave and pulsed laser light of a harmonic wave.

The laser light may be delivered in an inert gas atmosphere such as noble gas or nitrogen. This can suppress the roughness of a semiconductor surface due to the laser irradiation and also suppress variation in threshold voltage caused by variation in interface state density.

By the aforementioned laser irradiation, the semiconductor film 503 with improved crystallinity is formed. Alternatively, a polycrystalline semiconductor may be formed in advance by a sputtering method, a plasma CVD method, a thermal CVD method, or the like.

Although the semiconductor film 503 is crystallized in this embodiment mode, the semiconductor film 503 may remain amorphous or microcrystalline without being crystallized and may be subjected to a later-described process. A TFT using an amorphous semiconductor or a microcrystalline semiconductor has advantages of low cost and high yield because the number of manufacturing steps is smaller than that of a TFT using a polycrystalline semiconductor.

An amorphous semiconductor can be obtained by glow discharge decomposition of a gas containing silicon. As a typical gas containing silicon, SiH₄, and Si₂H₆ are given. This gas containing silicon may be diluted with hydrogen or with hydrogen and helium.

Note that a semi-amorphous semiconductor refers to a semiconductor with an intermediate structure between an amorphous semiconductor and a crystalline semiconductor (including a single-crystal semiconductor and a polycrystalline semiconductor). The semi-amorphous semiconductor is a semiconductor having a third state that is stable in terms of free energy and is a crystalline substance having a short-range order and lattice distortion which can be dispersed with its grain diameter of 0.5 to 20 nm in a non-single-crystal semiconductor film.

In order to terminate dangling bonds, the semi-amorphous semiconductor film contains hydrogen or halogen at a rate of at least 1 at. % or more. In this specification, such a semiconductor is referred to as a semi-amorphous semiconductor (SAS) for convenience. Moreover, a noble gas element such as helium, argon, krypton, or neon may be contained therein to further promote lattice distortion, so that stability is enhanced and a favorable semi-amorphous semiconductor can be obtained.

As a typical semi-amorphous semiconductor, semi-amorphous silicon can be given. A Raman spectrum of the semi-amorphous silicon is shifted to a lower wavenumber than 520 cm⁻¹. The diffraction peaks of (111) and (220) which are thought to be derived from a Si crystalline lattice are observed by X-ray diffraction.

In addition, semi-amorphous silicon can be obtained by glow discharge decomposition of a gas containing silicon. As a typical gas containing silicon, SiH₄ is given, and Si₂H₆, SiH₂Cl₂, SiHCl₃, SiCl₄, SiF₄, or the like can be used as well as SiH₄. The gas containing silicon may be diluted with hydrogen or with a gas in which one or more of noble gas elements selected from helium, argon, krypton, or neon are added to hydrogen; therefore, the semi-amorphous silicon film can be easily formed. It is preferable that the gas containing silicon be diluted with a dilution ratio in the range of from 2 to 1000 times.

Further, a carbide gas such as CH₄ or C₂H₆, a germanium gas such as GeH₄ or GeF₄, F₂, or the like may be mixed into the gas containing silicon so as to adjust the energy bandwidth within the range of from 1.5 to 2.4 eV or from 0.9 to 1.1 eV.

For example, in the case of using a gas in which H₂ is added to SiH₄ or a gas in which F₂ is added to SiH₄, the subthreshold coefficient (subthreshold swing) of the TFT can be less than or equal to 0.35 V/dec, typically 0.25 to 0.09 V/dec, and the mobility of carriers can be 10 cm²/Vs when the TFT is manufactured using the formed semi-amorphous silicon. When a 19-stage ring oscillator is formed of the TFT using the above-described semi-amorphous silicon, for example, the oscillation frequency is greater than or equal to 1 MHz, preferably, greater than or equal to 100 MHz, at a power supply voltage of 3 to 5 V. In addition, at a power supply voltage of 3 to 5 V, delay time per one stage of an inverter can be 26 ns, preferably less than or equal to 0.26 ns.

Next, as shown in FIG. 1B, the semiconductor film 503 is etched, thereby forming an island-shaped semiconductor film 504, an island-shaped semiconductor film 505 and an island-shaped semiconductor film 506. Then, a gate insulating film 507 is formed to cover the island-shaped semiconductor films 504 to 506. The gate insulating film 507 can be formed by using a film including silicon nitride, silicon oxide, silicon oxide containing nitrogen, or silicon nitride containing oxygen as a single layer or a stacked layer by a plasma CVD method, a sputtering method, or the like. In the case of stacking layers, for example, a three-layer structure of a silicon oxide film, a silicon nitride film, and a silicon oxide film formed in order from the substrate side is preferably employed.

Next, gate electrodes 510 to 512 are formed as shown in FIG. 1C. In this embodiment mode, the gate electrodes 510 to 512 are formed in such a way that tantalum nitride and tungsten are stacked in order by a sputtering method and then etching is performed with a resist 513 used as a mask. The material, structure, and manufacturing method of the gate electrodes 510 to 512 are not limited to these and can be selected as appropriate. For example, a stacked-layer structure of silicon doped with an impurity imparting n-type conductivity and nickel silicide or a stacked-layer structure of silicon doped with an impurity imparting n-type conductivity and tungsten silicide may be employed. Alternatively, a single layer of various conductive materials may be used.

The resist mask may be replaced by a mask of silicon oxide or the like. In this case, a step of patterning to form a mask of silicon oxide, silicon oxide containing nitrogen, or the like (called a hard mask) is added; however, the gate electrodes 510 to 512 can have desired widths because the film decrease of the hard mask is less than that of the resist mask at the time of etching. The gate electrodes 510 to 512 may be formed as selected by a droplet discharging method without using the resist 513.

As the conductive material, various materials can be selected depending on the function of a conductive film. When the gate electrodes and the antenna are formed at the same time, the material may be selected in consideration of their functions.

As an etching gas for etching the gate electrodes, a mixed gas of CF₄, Cl₂, and O₂, or a Cl₂ gas is employed, though the etching gas is not limited to this.

Next, as shown in FIG. 1D, the island-shaped semiconductor film 505 serving as a p-channel TFT is covered with a resist 514, and the island-shaped semiconductor films 504 and 506 are doped with an impurity element imparting n-type conductivity (typically P (phosphorus) or As (arsenic)) at low concentration by using the gate electrodes 510 and 512 as a mask (first doping process).

The first doping process is performed under the condition where the dose is in the range of from 1×10¹³ to 6×10¹³/cm² and the accelerating voltage is in the range of from 50 to 70 keV; however, the condition is not limited to this. In the first doping process, the doping is performed through the gate insulating film 507, and a pair of low-concentration impurity regions 516 and a pair of low-concentration impurity regions 517 are formed in the island-shaped semiconductor films 504 and 506, respectively. Further, the first doping process may be performed without covering with the resist the island-shaped semiconductor film 505 serving as the p-channel TFT.

Next, as shown in FIG. 1E, after removing the resist 514 by ashing or the like, a resist 518 is newly formed so as to cover the island-shaped semiconductor films 504 and 506 serving as n-channel TFTs. Then, the island-shaped semiconductor film 505 is doped with an impurity element imparting p-type conductivity (typically B (boron)) at high concentration by using the gate electrode 511 as a mask (second doping process).

The second doping process is performed under the condition where the dose is in the range of from 1×10¹⁶ to 3×10¹⁶/cm² and the accelerating voltage is in the range of from 20 to 40 keV. In the second doping process, the doping is performed through the gate insulating film 507, and a pair of p-type high-concentration impurity regions 519 is formed in the island-shaped semiconductor film 505.

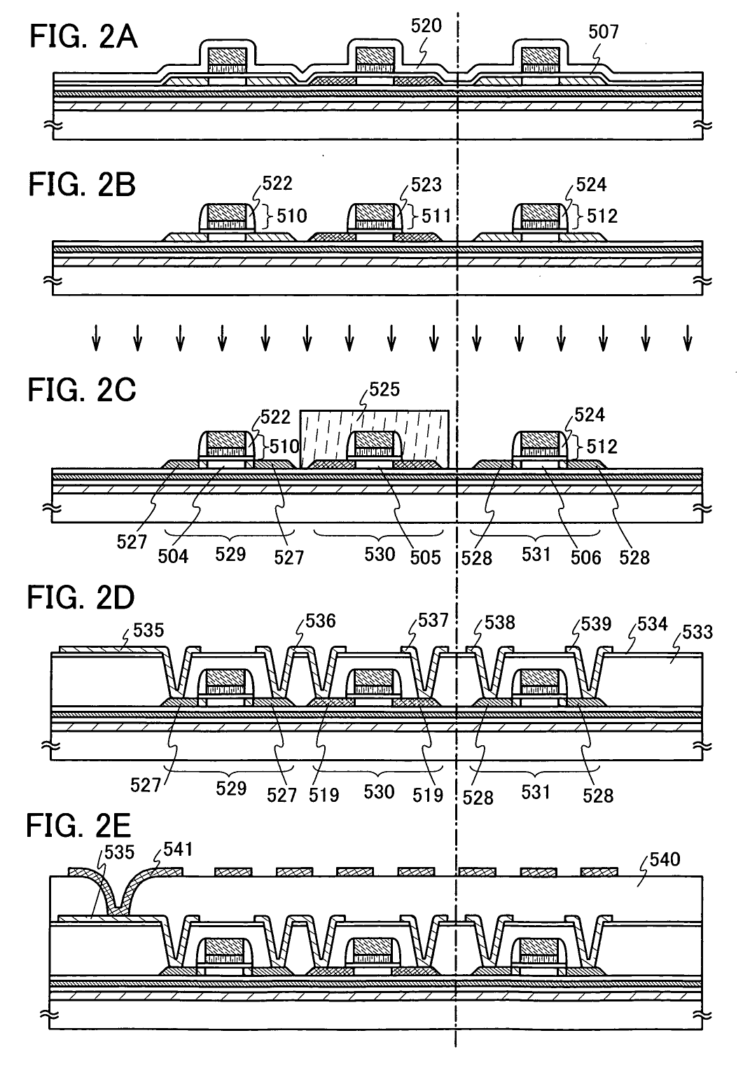

Next, as shown in FIG. 2A, after removing the resist 518 by ashing or the like, an insulating film 520 is formed so as to cover the gate insulating film 507 and the gate electrodes 510 to 512. In this embodiment mode, the insulating film 520 is a 100-nm-thick silicon oxide film formed by a plasma CVD method.

After that, the insulating film 520 and the gate insulating film 507 are partially etched by an etchback method to form sidewalls 522 to 524 in a self-aligned manner so as to be in contact with sides of the gate electrodes 510 to 512, as shown in FIG. 2B. A mixed gas of CHF₃ and He is used as an etching gas. Note that the step of forming the sidewalls is not limited thereto.

When the insulating film 520 is formed, the insulating film 520 may also be formed at a rear surface of the first substrate 500. In this case, the insulating film formed at the rear surface of the first substrate 500 may be etched away as selected by using a resist.

The sidewalls 522 and 524 will serve as masks in, subsequently, doping with an impurity imparting n-type conductivity at high concentration to form low-concentration impurity regions or non-doped off-set regions below the sidewalls 522 and 524. Therefore, in order to control the widths of the low-concentration impurity regions or the off-set regions, the size of the sidewalls 522 and 524 may be adjusted by changing, as appropriate, the film thickness of the insulating film 520 or the condition at the etchback method in forming the sidewalls 522 and 524.

Next, as shown in FIG. 2C, a resist 525 is newly formed so as to cover the island-shaped semiconductor film 505 serving as the p-channel TFT. Then, an impurity element imparting n-type conductivity (typically phosphorus or arsenic) is added at high concentration by using the gate electrodes 510 and 512 and the sidewalls 522 and 524 as masks (third doping process).

The third doping process is performed under the condition where the dose is in the range of from 1×10¹³ to 5×10¹⁵/cm² and the accelerating voltage is in the range of from 60 to 100 keV. In the third doping process, a pair of n-type high-concentration impurity regions 527 and a pair of n-type high-concentration impurity regions 528 are formed in the island-shaped semiconductor films 504 and 506, respectively.

After removing the resist 525 by ashing or the like, the impurity regions may be thermally activated. For example, after a silicon oxide film that contains nitrogen is formed at a film thickness of 50 nm, heat treatment may be performed in a nitrogen atmosphere at a temperature of 550° C. for four hours.

After a silicon nitride film containing hydrogen is formed in 100 nm thick, heat treatment may be performed thereon at 410° C. for 1 hour in a nitrogen atmosphere for hydrogenation of the island-shaped semiconductor films 504 to 506. Alternatively, heat treatment may be performed at 300 to 450° C. for 1 to 12 hours in an atmosphere containing hydrogen for hydrogenation of the island-shaped semiconductor films 504 to 506. As another means for the hydrogenation, plasma hydrogenation (using hydrogen that is excited by plasma) may be performed. Through the hydrogenation process, dangling bonds can be terminated by thermally excited hydrogen. After attaching the semiconductor element onto a second substrate 548 that is flexible in a later process, a defect may be formed in the semiconductor film by bending the second substrate 548. However, even in this case, the defect can be terminated by the hydrogen in the semiconductor film when the concentration of hydrogen in the semiconductor film is set in the range of from 1×10¹⁹ to 1×10²² atoms/cm³, preferably from 1×10¹⁹ to 5×10²⁰ atoms/cm³, by the hydrogenation. Further, in order to terminate the defect, halogen may be included in the semiconductor film.

According to a series of the foregoing steps, an n-channel TFT 529, a p-channel TFT 530, and an n-channel TFT 531 are formed. When the size of the sidewall is adjusted by changing, as appropriate, the condition at the etchback method or the film thickness of the insulating film 520 in the manufacturing steps described above, the TFT can have a channel length of 0.2 to 2 μm. Although the TFTs 529 to 531 each have a top-gate structure in this embodiment mode, they may have a bottom-gate structure (inverted-staggered structure).

Although this embodiment mode shows an electrically-isolated TFT as an example of a semiconductor element, a semiconductor element used for an integrated circuit is not limited to this, and any kind of circuit element can be used.

After that, a passivation film for protecting the TFTs 529 to 531 may be formed. It is preferable that the passivation film be formed using silicon nitride, silicon nitride containing oxygen, aluminum nitride, aluminum oxide, silicon oxide, or the like which can prevent the penetration of alkali metal or alkaline-earth metal into the TFTs 529 to 531. Specifically, for example, a silicon oxide film containing nitrogen having a thickness of approximately 600 nm can be used as the passivation film. In this case, the hydrogenation step may be performed after forming the silicon oxide film containing nitrogen. In this manner, three layers of insulating films of silicon oxide containing nitrogen, silicon nitride containing hydrogen, and silicon oxide containing nitrogen are formed over the TFTs 529 to 531. However, the structures and the materials of these films are not limited thereto. Since with the above structure, the TFTs 529 to 531 are covered with the base film 502 and the passivation film, it is possible to prevent alkali metal such as sodium or alkaline-earth metal from diffusing into the semiconductor film used for the semiconductor element, thereby preventing an adverse effect on characteristics of the semiconductor element.

Next, as shown in FIG. 2D, a first interlayer insulating film 533 is formed so as to cover the TFTs 529 to 531. The first interlayer insulating film 533 can be formed of a heat-resistant organic resin such as polyimide, acrylic, or polyamide. Instead of the aforementioned organic resins, a low dielectric constant material (low-k material), a resin including a Si—O—Si bond (hereinafter also called a siloxane-based resin), or the like can also be used. Siloxane has a skeleton structure of a bond of silicon (Si) and oxygen (O). As a substituent, an organic group containing at least hydrogen (such as an alkyl group or aromatic hydrocarbon (an aryl group)) is used. Alternatively, a fluoro group may be used as the substituent. Further alternatively, a fluoro group and an organic group containing at least hydrogen may be used as the substituent. The first interlayer insulating film 533 can be formed by spin coating, dipping, spray coating, a droplet discharging method (an ink-jet method, screen printing, offset printing, or the like), a doctor knife, a roll coater, a curtain coater, a knife coater, or the like, depending on the material thereof. Alternatively, the first interlayer insulating film 533 can be formed using an inorganic material such as silicon oxide, silicon nitride, silicon oxide containing nitrogen, silicon nitride containing oxygen, PSG (phosphosilicate glass), PBSG (phosphoborosilicate glass), BPSG (borophosphosilicate glass), or an alumina film. Insulating films of these may be stacked to form the first interlayer insulating film 533.

Further, a second interlayer insulating film 534 is formed over the first interlayer insulating film 533 in this embodiment mode. The second interlayer insulating film 534 may be a film including carbon such as diamond-like carbon (DLC) or carbon nitride (CN), a silicon oxide film, a silicon nitride film, a silicon nitride film containing oxygen, or the like formed by a plasma CVD method, atmospheric pressure plasma, or the like. Alternatively, a photosensitive or nonphotosensitive organic material such as polyimide, acrylic, polyamide, a resist, or benzocyclobutene; a siloxane-based resin; or the like may be used.

Filler may be mixed into the first interlayer insulating film 533 or the second interlayer insulating film 534 in order to prevent the first interlayer insulating film 533 or the second interlayer insulating film 534 from being separated or cracked due to stress generated by a difference in coefficient of thermal expansion between the first interlayer insulating film 533 or the second interlayer insulating film 534 and a conductive material of a wiring that is formed later, or the like.

Next, contact holes are formed in the first interlayer insulating film 533 and the second interlayer insulating film 534; and then, wirings 535 to 539 are formed so as to be connected to the TFTs 529 to 531 (see FIG. 2D). Although a mixed gas of CHF₃ and He is used for etching in opening the contact holes, the gas is not limited thereto. In this embodiment mode, the wirings 535 to 539 are formed of aluminum. Alternatively, the wirings 535 to 539 may be formed as a five-layer structure of titanium (Ti), titanium nitride, aluminum containing silicon (Al—Si), titanium (Ti), and titanium nitride by a sputtering method.

By mixing silicon (Si) into aluminum (Al), it is possible to prevent generation of hillock at the time of baking the resist in forming the wirings. Instead of silicon (Si), copper (Cu) may be mixed in aluminum at a rate of approximately 0.5%. When an aluminum layer containing silicon (Al—Si layer) is sandwiched between titanium (Ti) or titanium nitride, the resistance against the hillock is improved further. It is preferable to use the hard mask described above which is made of silicon oxide containing nitrogen or the like in etching. The material and the forming method of the wirings are not limited thereto, and the aforementioned material used for the gate electrode may be used.

The wirings 535 and 536 are connected to the high-concentration impurity regions 527 of the n-channel TFT 529. The wirings 536 and 537 are connected to the high-concentration impurity regions 519 of the p-channel TFT 530. The wirings 538 and 539 are connected to the high-concentration impurity regions 528 of the n-channel TFT 531.

Next, as shown in FIG. 2E, a third interlayer insulating film 540 is formed over the second interlayer insulating film 534 so as to cover the wirings 535 to 539. The third interlayer insulating film 540 has an opening portion at which the wiring 535 is partially exposed. The third interlayer insulating film 540 can be formed using an organic resin film, an inorganic insulating film, or a siloxane-based insulating film. As the organic resin film, for example, acrylic, polyimide, polyamide, or the like can be used, and as the inorganic insulating film, silicon oxide, silicon nitride containing oxygen, silicon oxide containing nitrogen, or the like can be used. Note that a mask used to form the opening portion can be formed by a droplet discharging method or a printing method. The third interlayer insulating film 540 itself can be formed by a droplet discharging method or a printing method.

Next, an antenna 541 is formed over the third interlayer insulating film 540. The antenna 541 can have a structure of lower wiring/antenna base layer/copper plating layer. In this case, a nitride film of an alloy of nickel and any of titanium, tantalum, tungsten, or molybdenum is used as the antenna base layer.

Alternatively, the antenna 541 may have a structure of lower wiring/first base layer/second base layer/copper plating layer. In this case, the first antenna base layer is a nitride film of any of titanium, tantalum, tungsten, or molybdenum, and the second antenna base layer is a nickel nitride film.

The antenna 541 is an internal antenna which is formed inside a semiconductor device capable of wireless communication, and is electrically connected to the antenna 102 which is an external antenna in a later step.

After forming the antenna 541, a separation insulating film 542 is formed to cover the antenna 541. The separation insulating film 542 can be formed using an organic resin film, an inorganic insulating film, a siloxane-based resin film, or the like. The inorganic insulating film is, for example, a DLC film, a carbon nitride film, a silicon oxide film, a silicon nitride film containing oxygen, a silicon nitride film, an aluminum nitride film, an aluminum oxynitride film, or the like. Moreover, the separation insulating film 542 may be formed with a film containing polystyrene, a stack of a carbon nitride film and a silicon nitride film, or the like. In this embodiment mode, the separation insulating film 542 is a silicon nitride film.

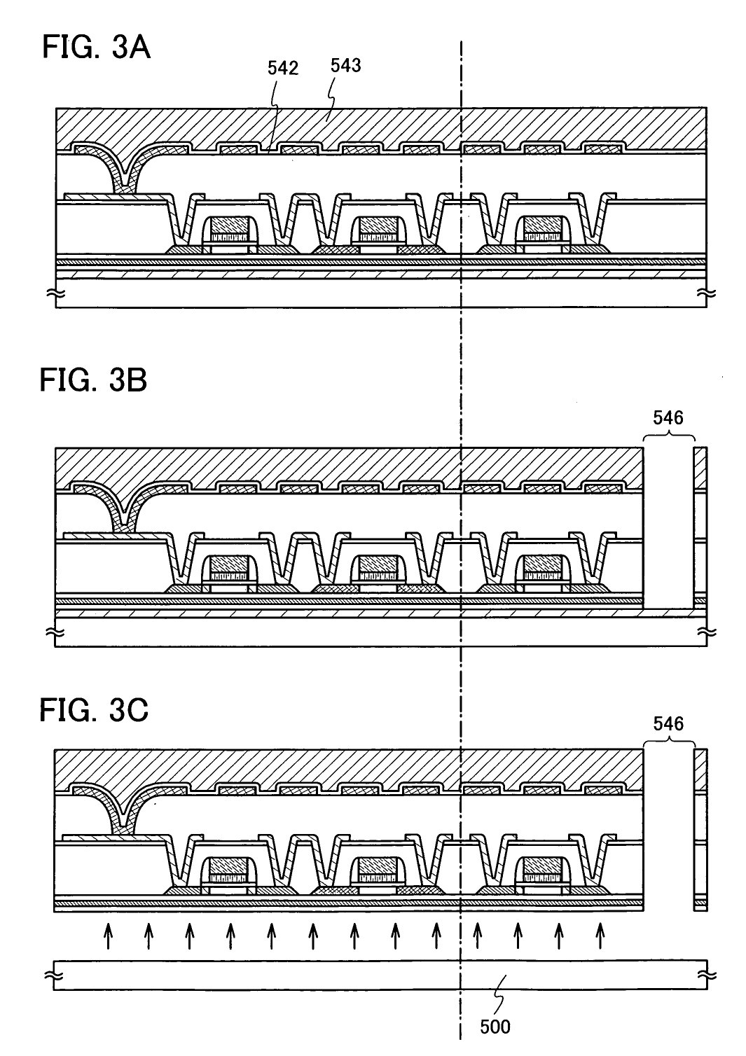

Next, a protection layer 543 is formed to cover the separation insulating film 542, as shown in FIG. 3A. The protection layer 543 is formed of a material that can protect the TFTs 529 to 531 and the wirings 535 to 539 when the separation layer 501 is later etched away. For example, the protection layer 543 can be formed by applying over the entire surface, an epoxy-based resin, an acrylate-based resin, or a silicon-based resin, which is soluble in water or in alcohols.

In this embodiment mode, the protection layer 543 is formed in the following manner: a water-soluble resin (manufactured by Toagosei Co., Ltd.: VL-WSHL10) is applied so as to have a thickness of 30 μm by a spin coating method, and exposed to light for 2 minutes for temporary curing, and then, its rear surface is exposed to UV light for 2.5 minutes and its front surface is exposed to UV light for 10 minutes, 12.5 minutes in total, so that the resin is fully cured. Note that, in the case where a plurality of organic resins are stacked, the stacked organic resins might be partly melted depending on a solvent to be used, during application or baking, or the adhesiveness might become too high. Therefore, in the case where organic resins that are soluble in the same solvent are used for the separation insulating film 542 and the protection layer 543, it is preferable to form an inorganic insulating film (e.g., a silicon nitride film, a silicon nitride film containing oxygen, an aluminum nitride film, or an aluminum oxynitride film) so as to cover the separation insulating film 542 in order that the protection layer 543 may be smoothly removed in a later step.

Next, a groove 546 is formed to isolate the ID chips from each other, as shown in FIG. 3B. The groove 546 may have such depth that the separation layer 501 is exposed. The groove 546 can be formed by dicing, scribing, a photolithography method, or the like. Note that when the ID chips formed over the first substrate 500 do not need to be isolated from each other, the groove 546 is not necessarily formed.

Next, the separation layer 501 is etched away, as shown in FIG. 3C. In this embodiment mode, halogen fluoride is used as etching gas, and the gas is introduced through the groove 546. In this embodiment mode, for example, etching is performed by using ClF₃ (chlorine trifluoride) at 350° C. at a flow rate of 300 sccm with an atmospheric pressure of 8×10² Pa (6 Torr) for 3 hours. Alternatively, a gas in which nitrogen is mixed into a ClF₃ gas may be used. When halogen fluoride such as ClF₃ is used, the separation layer 501 is etched a selected, so that the first substrate 500 can be separated from the TFTs 529 to 531. Further, the halogen fluoride may be either a gas or a liquid.

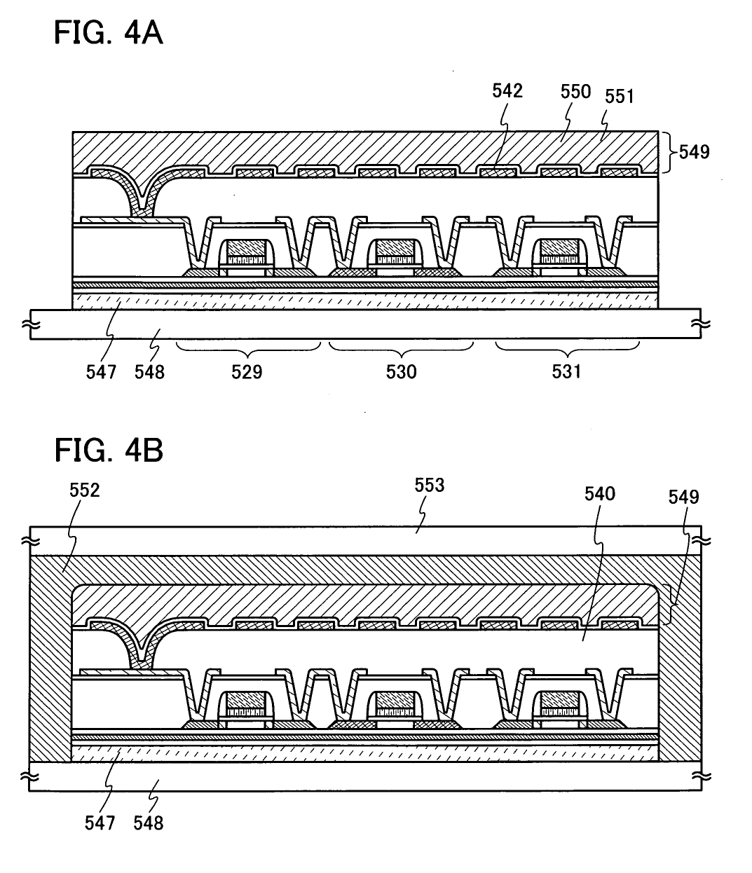

Subsequently, as shown in FIG. 4A, the TFTs 529 to 531 that have been separated are attached to the second substrate 548 with the use of an adhesive 547. A material which can attach the second substrate 548 and the base film 502 to each other is used for the adhesive 547. As the adhesive 547, for example, various curable adhesives such as a reactive curable adhesive, a thermosetting adhesive, and a photo curable adhesive such as an ultraviolet curable adhesive, and an anaerobic adhesive can be used.

The second substrate 548 may be formed using a flexible organic material such as paper or plastic or a flexible inorganic material. ARTON (manufactured by JSR Corporation) formed of polynorbornene having a polar group can be used for a plastic substrate. In addition, polyester typified by polyethylene terephthalate (PET); polyether sulfone (PES); polyethylene naphthalate (PEN); polycarbonate (PC); nylon; polyetheretherketone (PEEK); polysulfone (PSF); polyetherimide (PEI); polyarylate (PAR); polybutylene terephthalate (PBT); polyimide; an acrylonitrile butadiene styrene resin; polyvinyl chloride; polypropylene; polyvinyl acetate; an acrylic resin; and the like can be given. It is preferable that the second substrate 548 have thermal conductivity as high as 2 to 30 W/mK in order to diffuse heat generated in an integrated circuit.

The external antenna 102 (see FIG. 5A) is formed over the second substrate 548 so as to be connected to at least one of the TFTs 529 to 531 or the internal antenna 541. The external antenna 102 is formed by an ink-jet method. The antenna is drawn in such a manner that a titanium paste containing a titanium fine particle, a nickel paste containing nickel and a copper paste containing copper are mixed at desired rates and the mixture is discharged from a nozzle of an ink-jet apparatus. After drawing the antenna, heat treatment is performed in a reducing atmosphere to form a titanium-nickel-copper alloy. Heat treatment is further performed so that the obtained titanium-nickel-copper alloy has crystallinity. Thus, the titanium-nickel-copper alloy is crystallized. In this embodiment mode, an austenite layer is formed in the titanium-nickel-copper alloy by heat treatment for crystallization.

Next, an insulating layer 549 is formed to cover the separation insulating film 542, as shown in FIG. 4A. The insulating layer 549 can be formed of an organic resin such as polyimide, epoxy, acrylic, or polyamide. Instead of the aforementioned organic resins, an inorganic resin such as a siloxane-based material can be used. As a substituent of a siloxane-based material, an organic group containing at least hydrogen (such as an alkyl group or aromatic hydrocarbon) is used. Alternatively, a fluoro group may be used as the substituent. Further alternatively, a fluoro group and an organic group containing at least hydrogen may be used as the substituent.

Next, an adhesive 552 is applied onto the insulating layer 549, and a third substrate 553 is attached thereto, as shown in FIG. 4B. The third substrate 553 can be formed of a similar material to the second substrate 548. The adhesive 552 may have a thickness of from, for example, 10 to 200 μm.

A material which can attach the third substrate 553 and the insulating layer 549 to each other is used for the adhesive 552. As the adhesive 552, for example, various curable adhesives such as a reactive curable adhesive, a thermosetting adhesive, and a photo curable adhesive such as an ultraviolet curable adhesive, and an anaerobic adhesive can be used.

Although the third substrate 553 is attached to the insulating layer 549 by using the adhesive 552 in this embodiment mode, the present invention is not limited to this structure. The insulating layer 549 and the third substrate 553 can also be attached to each other directly when a resin that functions as an adhesive is used for an insulator 550 of the insulating layer 549.

In the semiconductor device capable of wireless communication which is formed in this embodiment mode, the strength is secured by the antenna formed using an alloy having a superelastic property or a shape-memory alloy; therefore, strength is not required for the second substrate 548 or the third substrate 553. Therefore, in this embodiment mode, as the second substrate 548 or the third substrate 553, any base material may be used as long as it is flat (sheet-like) and flexible. For example, plastic which is thinned such that it cannot be used conventionally due to the strength, a film or paper may be used. According to the present invention, a semiconductor device capable of wireless communication with a thickness of 0.76 mm or less, preferably 0.25 mm or less, more preferably 0.1 mm or less can be formed.

Even if the semiconductor device capable of wireless communication which is formed in this embodiment mode is bent or wrinkles occur in the semiconductor device in usage or storage, the shape of the semiconductor device returns to a shape having a plane surface by heating.

### Embodiment Mode 2

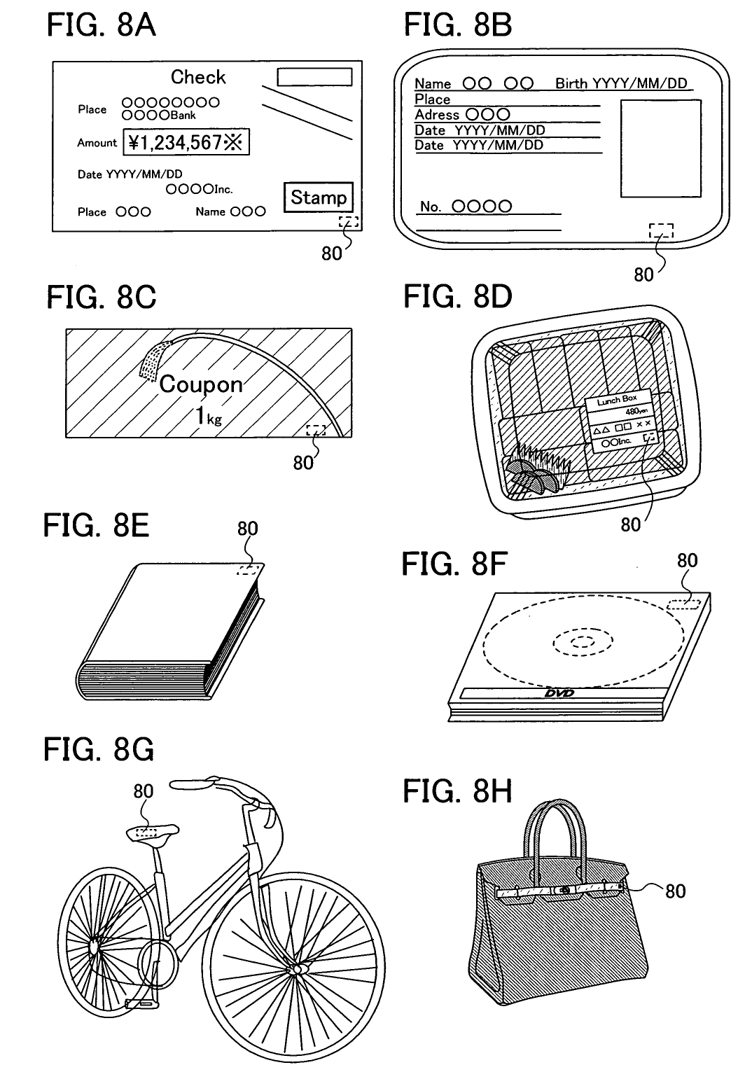

Embodiment Mode 2 will explain application examples of a semiconductor device capable of wireless communication of the present invention. The application range of a semiconductor device capable of wireless communication of the present invention is so wide that it can be applied to any product in order that the information of an object such as the history is revealed without contact and utilized in production, management, and the like. For example, a semiconductor device of the present invention may be incorporated in bills, coins, securities, certificates, bearer bonds, containers for packaging, books, recording media, personal belongings, vehicles, foods, clothes, healthcare items, livingware, medicals, electronic appliances, and the like. These examples are explained with reference to FIGS. 8A to 8H.

The bills and coins correspond to currency circulating in the market and include notes that are current as money in a specific area (cash voucher), memorial coins, and the like. The securities include checks, stock certificates, promissory notes, and the like (FIG. 8A). The certificates include driver's licenses, resident cards, and the like (FIG. 8B). The bearer bonds include stamps, rice coupons, various gift coupons, and the like (FIG. 8C). The containers for packaging include paper for wrapping a box lunch or the like, plastic bottles, and the like (FIG. 8D). The books include documents and the like (FIG. 8E). The recording media include DVD software, video tapes, and the like (FIG. 8F). The vehicles include wheeled vehicles such as bicycles, vessels, and the like (FIG. 8G). The personal belongings include bags, glasses, and the like (FIG. 8H). The foods include food items, beverages, and the like. The clothes include clothing, footwear, and the like. The healthcare items include medical devices, health appliances, and the like. The livingware includes furniture, lighting apparatuses, and the like. The medicals include medicines, agricultural chemicals, and the like. The electronic appliance refers to liquid crystal display devices, EL display devices, television sets (TV receivers or thin TV receivers), mobile phones, or the like.

When a semiconductor device 80 capable of wireless communication of the present invention is incorporated in bank notes, coins, securities, certificates, bearer bonds and the like, forgery can be prevented. When the semiconductor device 80 capable of wireless communication is incorporated in containers for packaging, books, recording media, personal belongings, foods, livingware, electronic appliances, and the like, the efficiency of an inspection system, a rental system, or the like can be improved. When the semiconductor device 80 capable of wireless communication is incorporated in vehicles, healthcare items, medicals, and the like, forgery and theft of them can be prevented and medicines can be prevented from being taken in a wrong manner. The semiconductor device 80 capable of wireless communication may be attached to a surface of a product or incorporated into a product. Further, the semiconductor device 80 may be incorporated into paper of a book, or an organic resin of a package, for example.

In this manner, the efficiency of an inspection system or a rental system can be promoted by providing a semiconductor device capable of wireless communication for packaging containers, recording media, personal belongings, food, clothing, household goods, electronic appliances, or the like. Further, forgery or theft can be prevented by providing a semiconductor device capable of wireless communication for the vehicles. In addition, when a semiconductor device is implanted into creatures such as animals, each creature can be identified easily. For example, when a semiconductor device capable of wireless communication, which is provided with a sensor is implanted into creatures such as domestic animals, not only the year of birth, sex, breed, and the like but also the health condition such as the current body temperature can be easily managed. In particular, by using the semiconductor device shown in the above embodiment mode, it is possible to prevent a defect of the semiconductor device capable of wireless communication due to poor connection between the antenna and the IC chip even when the semiconductor device is provided to a curved surface or the product is bent.

A method for manufacturing a semiconductor device shown in this embodiment mode can be applied to the semiconductor device in any of the other embodiment modes described in this specification.

### Embodiment Mode 3

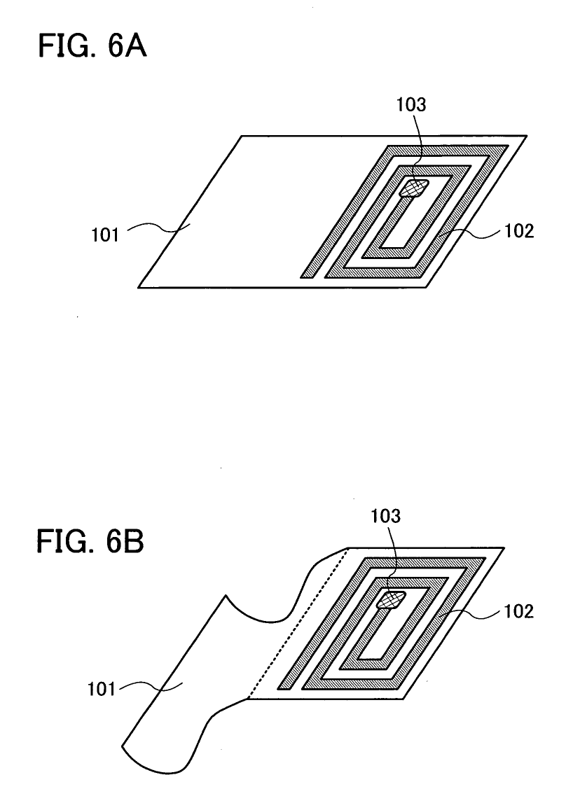

This embodiment mode will describe an example in which a semiconductor device capable of wireless communication of the present invention is applied to cards or tickets with reference to FIGS. 6A and 6B, FIGS. 9A and 9B, and FIGS. 10A and 10B.

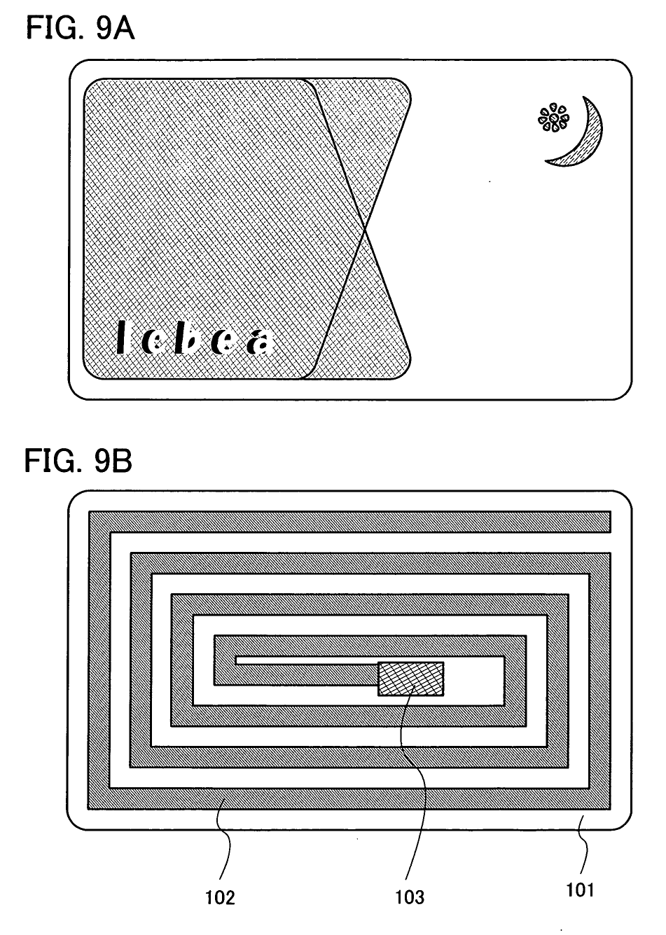

FIGS. 9A and 9B show an example in which the present invention is applied to a credit card or a prepaid card (a telephone card, a train ticket, or the like).

FIG. 9A shows an outer appearance of a prepaid card and FIG. 9B shows the inside thereof. The prepaid card shown in FIGS. 9A and 9B includes a semiconductor device 103 capable of wireless communication and an antenna 102 over a supporting substrate 101. The prepaid card keeps its shape by the antenna 102 formed using a shape-memory alloy or an alloy having a superelastic property.

FIGS. 6A and 6B show a case in which the antenna 102 is formed not entirely but locally over the supporting substrate 101.

When the antenna 102 is formed locally over the supporting substrate 101 (see FIG. 6A), the supporting substrate 101 curls up or is bent in some cases. Even if the shapes of the antenna 102 and a region over the supporting substrate 101 where the antenna 102 is formed are restored, a region over the supporting substrate 101 where the antenna 102 is not formed remains bent (see FIG. 6B).

However, an operation defect of the semiconductor device 103 does not occur due to the semiconductor device 103 being curved as long as the semiconductor device 103 capable of wireless communication is not formed in a region where the antenna 102 is not formed. That is, the antenna 102 or the semiconductor device 103 capable of wireless communication does not need to be formed in a region that is irrelevant to wireless communication.

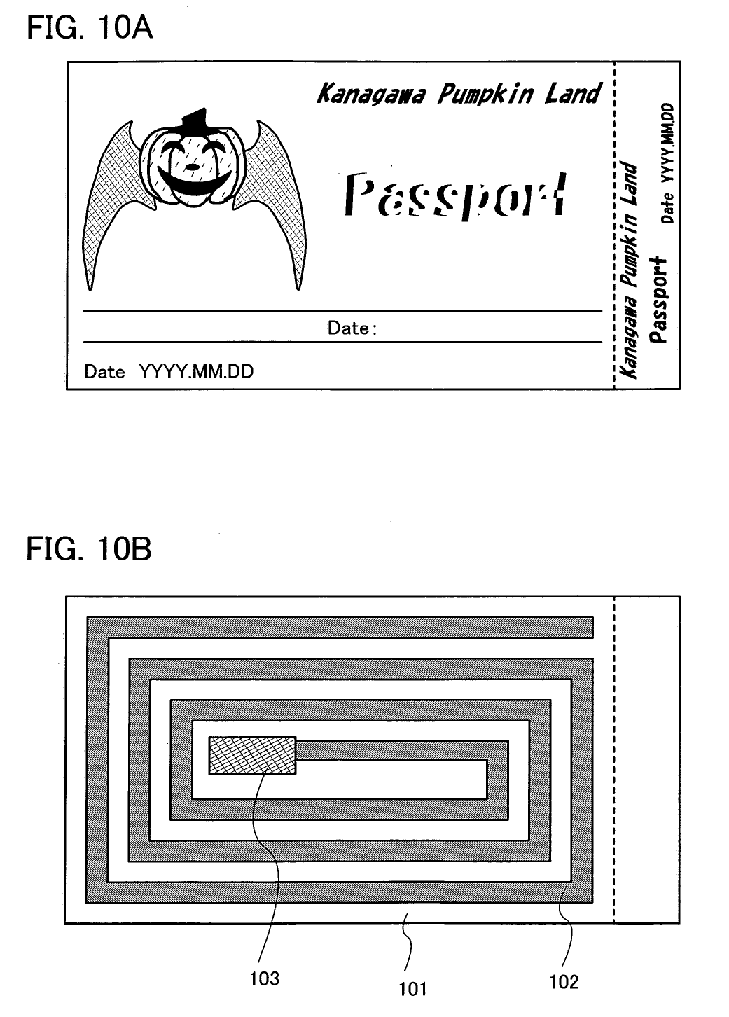

FIGS. 10A and 10B show an example in which the present invention is applied to a ticket, an entrance card or a passport of movies, amusement parks, leisure centers, theme parks, or the like.

FIG. 10A shows an outer appearance of a ticket and FIG. 10B shows an internal structure thereof. The antenna 102 and the semiconductor device 103 capable of wireless communication are not formed on a region of a ticket which is cut off.

Further, it is possible to manufacture a ticket, or the like in which the antenna 102 and the semiconductor device 103 capable of wireless communication are not formed in a region that is irrelevant to wireless communication such as a region where handwriting is performed, a region where printing is possible, or the like.

This application is based on Japanese Patent Application serial no. 2007-164552 filed with Japan Patent Office on Jun. 22, 2007, the entire contents of which are hereby incorporated by reference.

What is claimed is:

1. A semiconductor device comprising:
an antenna having a superelastic property or a shape-memory property over a substrate; and
a circuit including a thin film transistor over the substrate, which is electrically connected to the antenna.

2. The semiconductor device according to claim 1, wherein the antenna contains a transition metal.

3. The semiconductor device according to claim 2, wherein the transition metal is any one of vanadium, chromium, manganese, iron, and cobalt.

4. The semiconductor device according to claim 1, wherein the antenna contains any one of an alloy containing cadmium, an alloy containing titanium and nickel, an alloy containing nickel, an alloy containing copper, an alloy containing indium, and an alloy containing iron.

5. The semiconductor device according to claim 4,
wherein the alloy containing cadmium is any one of Au—Cd and Ag—Cd;
wherein the alloy containing titanium and nickel is any one of Ti—Ni, Ti—Ni—Cu, Ti—Ni—Fe, and Ti—Pd—Ni;
wherein the alloy containing nickel is Ni—Al;
wherein the alloy containing copper is any one of Cu—Al—Ni, Cu—Au—Zn, Cu—Sn, and Cu—Zn;
wherein the alloy containing indium is any one of In—Ti and In—Cd; and
wherein the alloy containing iron is any one of Fe—Pt, Fe—Pd, Fe—Mn—Si, and Fe—Ni—Co—Ti.

6. The semiconductor device according to claim 1, wherein the antenna contains an alloy containing any one of copper, aluminum, silver, gold, nickel, and titanium.

7. The semiconductor device according to claim 1, wherein the substrate is any one of a film, paper, and plastic.

8. A method for manufacturing a semiconductor device comprising:
forming an antenna having a superelastic property or a shape-memory property over a first substrate, wherein a method for forming the antenna comprises:
discharging a material containing metal by a printing method; and
heating the material;
providing a thin film transistor over the first substrate so as to be electrically connected to the antenna.

9. The method according to claim 8, wherein the printing method is an ink-jet method.

10. The method according to claim 8, wherein the material is crystallized after heating.

11. The method according to claim 8, wherein the first substrate is any one of a film, paper, and plastic.

12. The method according to claim 8, wherein the thin film transistor is formed over a second substrate, and then the thin film transistor is transferred from the second substrate to the first substrate.

13. The semiconductor device according to claim 1, wherein a thickness of the semiconductor device is 0.25 mm or less.
